(19) United States
(12) Patent Application Publication
(10) Pub. No.: US 2014/0084815 A1
(43) Pub. Date: Mar. 27, 2014

(54) Layered Cluster High Voltage RF Opto-Electric Multiplier for Charged Particle Accelerators

(71) Applicant: COMPACT PARTICLE ACCELERATION CORPORATION, Livermore, CA (US)

(72) Inventors: Vladimir Andreevich Joshkin, Dublin, CA (US); Yoko Parker, Pleasanton, CA (US)

(73) Assignee: Compact Particle Acceleration Corporation, Livermore, CA (US)

(21) Appl. No.: 13/626,648

(22) Filed: Sep. 25, 2012

(51) Int. Cl. H05H 9/02; H05K 13/00

(52) U.S. Cl. CPC H05H 9/02; H05K 13/0023
USPC 315/505; 29/825

(57) ABSTRACT

Circuitry is presented that can provide high-voltage radio-frequency pulses in the range of from a few volts to megavolts for charged particle accelerators. Individual pulse forming sections, such as transmission line transformers (TLTs) or blumleins, are formed in clusters. The pulse forming sections of each cluster are connected in series and have transmission lines ending in a ring structure. Multiple clusters can then be arranged with their rings aligned along the axis of the accelerator.

### BACKGROUND

1. Field of the Invention

This invention relates generally to linear accelerators and, more specifically, to the circuitry for supplying electrical pulses in such structures.

2. Background Information

Particle accelerators are used to increase the energy of electrically charged atomic particles. In addition to their use for basic scientific study, particle accelerators also find use in the development of nuclear fusion devices and for medical applications, such as cancer therapy. An example is described in U.S. Pat. No. 7,173,385. In order to accelerate the particles, a series of high frequency, high voltage pulse are applied along the axis of the accelerator. The greater the voltage and the greater frequency, the more effective the accelerator. To make such devices more practical, they should also be smaller is size and more efficient. Consequently, there is an ongoing need to make particle accelerators more powerful, more compact, and more efficient.

### SUMMARY OF THE INVENTION

According to a first set of general aspects, a particle accelerator is formed of a plurality of clusters. Each cluster includes: first and second transmission line sections, respectively ending in first and second annular electrodes centered along the axis of the accelerator; a capacitor section; and a plurality of pulsing forming lines connected in series between the first and second transmission line section. Each of the pulse forming lines includes a pulse generation section and a switch connected between an electrode of the capacitor section and a signal line conductor of the pulse generation section. At least a portion of the transmission line sections extend radially away from the axis of the accelerator with the pulse forming lines splayed out axially from an end of the transmission line section without the annular electrodes. The clusters are arranged so that their respective transmission line sections do not all extend away from the axis of the accelerator with the same axial angle.

Another set of aspects related to a method of forming a particle accelerator. The method includes forming a plurality of clusters, each cluster including a transmission line with first and second strip electrodes respectively ending in first and second annular electrodes, a capacitor section, and a plurality of pulsing forming lines. Each pulse forming line includes a pulse generation section and a switch. Forming each of the clusters includes: connecting the pulse forming lines in series between the first and second strip electrodes; connecting the switch of each pulse forming line between an electrode of the capacitor section and a signal line conductor of the corresponding pulse generation section; centering the first and second annular electrodes along the axis of the accelerator; arranging at least a portion of the strip electrodes to extend radially away from the axis of the accelerator; and arranging the pulse forming lines to be splayed out axially from an end of the transmission line section without the annular electrodes. The clusters are arranged so that their respective strip electrodes do not all extend away from the axis of the accelerator with the same axial angle.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIGS. 1A and 1B respectively show an example of a 2D and a 3D cluster stricter for a high-voltage, radio-frequency multiplier for a charged particle accelerator.

FIG. 2 shows an example of a 2D cluster layer device including output shaper.

FIG. 3 shows an equivalent electronic scheme of a cluster with the voltage multiplication produced by ladder-like elements forming a one layer cluster.

FIGS. 4A-D show some examples of different possible cluster designs.

FIGS. 5A and 5B show two examples of layered cluster devices.

FIGS. 6-9A are schematic views for several examples of the layered cluster device.

FIG. 9B shows the CAD simulated output of the layered cluster device vs. gap between layers.

FIG. 10 is a table showing simulated parameters for standard vertical stack of blumleins vs. layered cluster design formed of TLTs such as in FIG. 9.

### DETAILED DESCRIPTION

The following presents a number of aspects that can be incorporated in a compact accelerator of charged particles. In particular, it relates to the pulse-forming lines of the linear accelerators and presents devices that can provide high-voltage radio-frequency pulses in the range of from a few volts to megavolts for charged particle accelerators. The devices can use as input an external charge voltage (DC or AC) of, say, charge voltage U₀, and an optical pulse to create output RF pulses with a peak voltage of kU₀, where k>2. The exemplary embodiments present an efficient way of assembling strip and micro-strip pulse forming lines as layered clusters to provide a high voltage and very short electrical pulse to produce very high electrical fields (such as over 10 MV/m) for charged particle accelerators. In particular, these cluster can be built with transmission line transformers (TLTs), such as described in U.S. patent application Ser. No. 13/352,187, or blumleins, such as described in US patent publication number 2012-0146553 and developed further in U.S. patent application Ser. Nos. 13/610,051 and 13/610,069.

The presented arrangement can provide a compact device capable of providing nanosecond long impulses with voltage peak amplitude in the range from few kV to few MV. Compared to other generators, such as electronic tube devices and blumlein generators, the presented circuitry can be built with a limited number of switches (in the exemplary embodiment, SiC opto-switches). Further, it can be used for producing very high voltage impulses without significant power consumption and, as a result, the power dissipation can be much smaller, using a lower power light beam for triggering. The use of a layered cluster arrangement provides for a lower capacitive and inductive parasitic coupling between the individual RF strip and micro-strip devices. It also allows for the switches to have free space around their top surface due to a gap between layers, allowing for switch illumination from the contact side. Further, this arrangement allows for the building of an oil-free system.

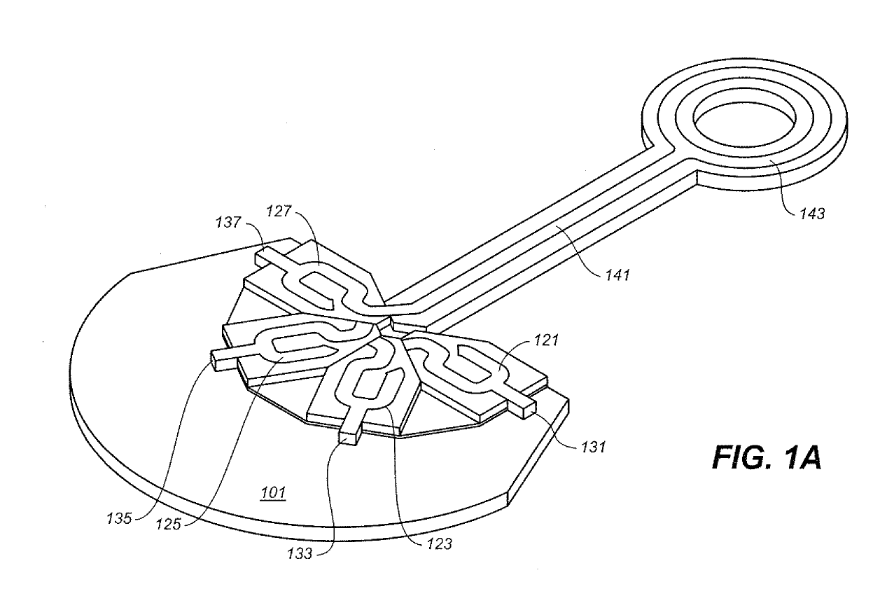

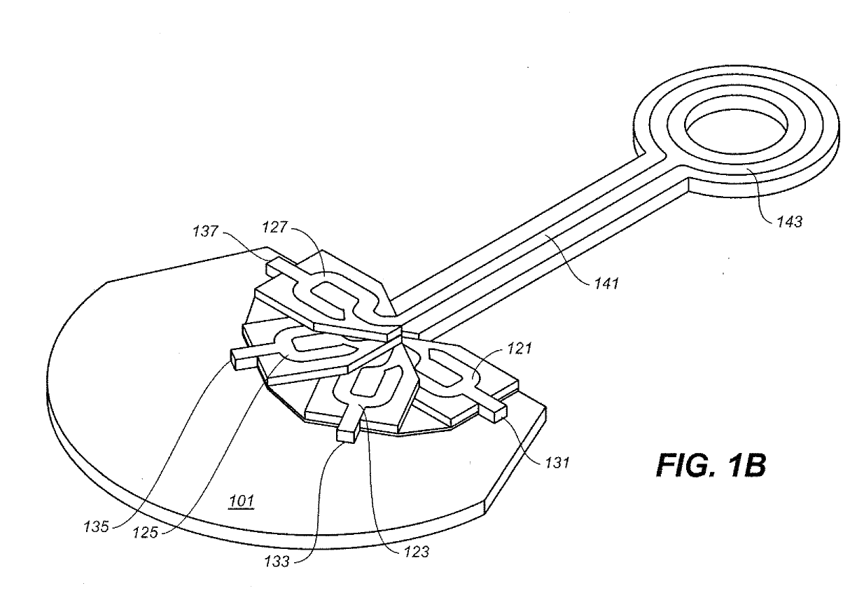

The exemplary embodiment presented here are pulse forming lines, such as transmission line transformers (TLTs) with or without RF transmission line pulse shapers or blumleins, that are arranged in layered 2D or 3D clusters, where cluster layers are stacked together, one on top of another. To provide higher voltage output, the pulse-forming lines from the same cluster are connected in series. Each cluster layer can be turned relative to the previous one in the plane of layer. All of the devices within a cluster can have the same input voltage, using either a common capacitor or separate capacitors in the switch section. The devices in the cluster can be arranged into a 2D or a 3D cluster layer, as shown in the examples of FIGS. 1A and 1B, respectively.

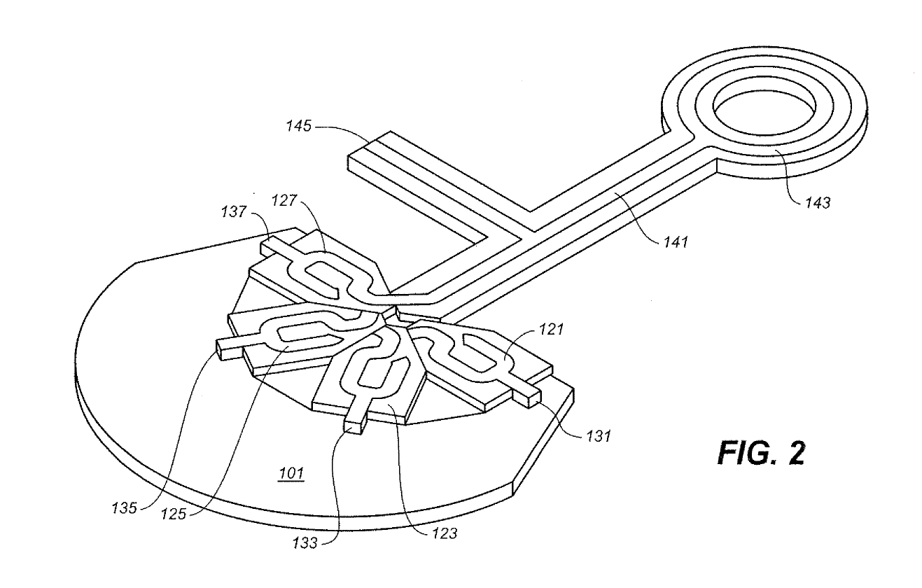

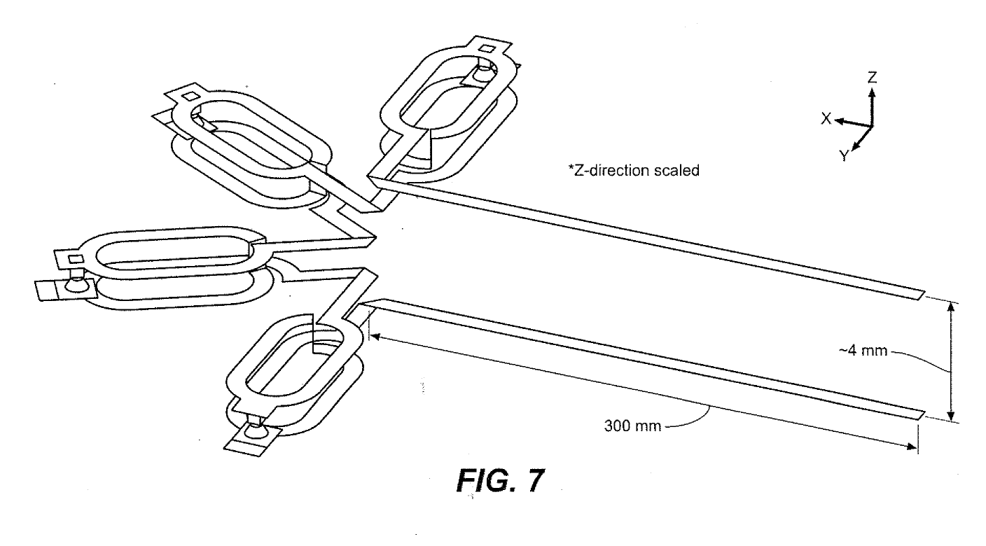

FIGS. 1A and 1B each show an example of a cluster. Each cluster layer includes a capacitor 101 and a set of, in this example, four pulse generating sections (121, 123, 125, 127) with a switch (131, 133, 135, 137 respectively) connected on one side to the capacitor. In this example, a single capacitor is used by all the switches of the layer, but each could have its own or share with fewer switches. The exemplary embodiment is shown with transmission line transformers (TLT) built of ladder line elements for the pulse generating section, although blumleins could also be used. The pulse generating section 121, 123, 125, 127 have their output connected in series and connect to the transmission line 141 that ends with annular, ring-like electrode 143, which has a hole for the accelerator beam (for example, for a dielectric wall accelerator built with high gradient insulator). In FIGS. 1A and 1B, only the top transmission line 141 and ring 143 are shown, with a second line and ring underneath not shown (see FIG. 7, below, for example). Depending on how the TLTs (or blumleins) are stacked, the cluster can have either a 2D (FIG. 1A) or a 3D (FIG. 1B) arrangement. In either the co-planar 2D or the 3D case, the outputs of the TLTs or blumleins are connected in series and spread out axially on the end opposite the ring. In the case where a better defined pulse may be needed, an output shaper can also be included. This is shown in FIG. 2, where an example of a 2D cluster layer device includes output shaper 145.

Although other switch types can be used, in the exemplary embodiments the switch is based on high electrical field assisted optical absorption such as that presented in U.S. patent application Ser. No. 12/963,456. More detail on such a suitable switch is described in: G. Caporaso, “New Trends in Induction Accelerator Technology”, Proceeding of the International Workshop on Recent Progress in Induction Linacs, Tsukuba, Japan, 2003; G. Caporaso, et. al., Nucl Instr. and Meth. in Phys. B 261, p. 777 (2007); G. Caporaso, et. al., “High Gradient Induction Accelerator”, PAC '07, Albuquerque, June 2007; G. Caporaso, et. al., “Status of the Dielectric Wall Accelerator”, PAC '09, Vancouver, Canada, May 2009; J. Sullivan and J. Stanley, “6H—SiC Photoconductive Switches Triggered Below Bandgap Wavelengths”, Power Modulator Symposium and 2006 High Voltage Workshop, Washington, D.C. 2006, p. 215 (2006); James S. Sullivan and Joel R. Stanley, “Wide Bandgap Extrinsic Photoconductive Switches” IEEE Transactions on Plasma Science, Vol. 36, no. 5, October 2008; and Gyawali, S. Fessler, C. M. Nunnally, W. C. Islam, N. E., “Comparative Study of Compensated Wide Band Gap Photo Conductive Switch Material for Extrinsic Mode Operations”, Proceedings of the 2008 IEEE International Power Modulators and High Voltage Conference, 27-31 May 2008, pp. 5-8. The switch can illuminated by a light source such a laser, where more detail on techniques related to illuminating the switch can be found in U.S. provisional patent application No. 61/680,782 and U.S. patent application Ser. No. 13/610,069.

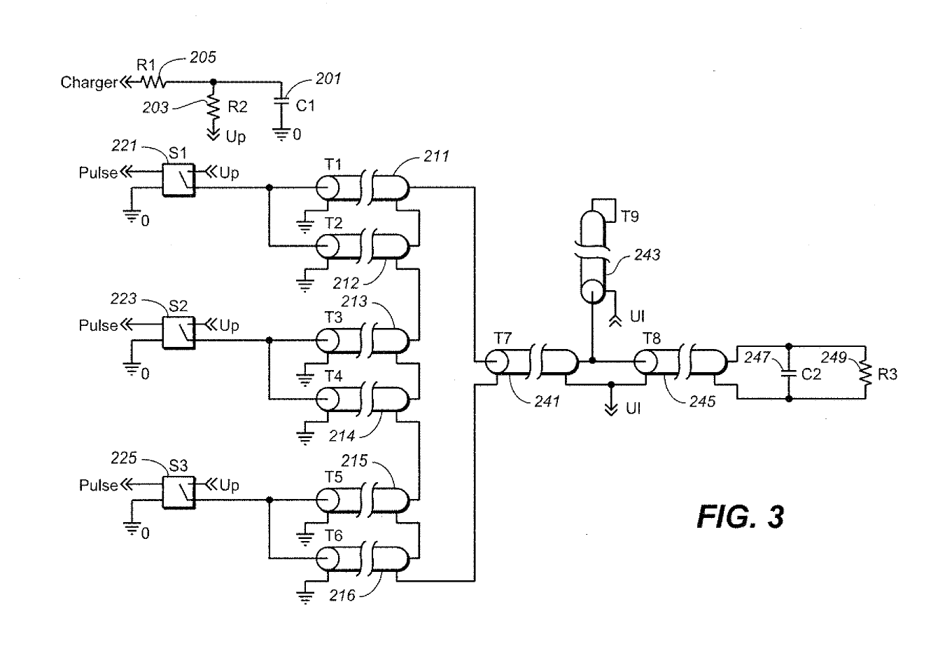

FIG. 3 shows an equivalent electronic scheme of a cluster with the voltage multiplication produced by ladder-like elements forming a one layer cluster. Here, a single layer 3 TLT cluster device with shaper is shown. Each opto-switch S1 221, S2 223, and S3 225 is connected to two ladder like elements T1 211, T2 212; T3 213, T4 214; and T5 215, T6 216, respectively. These elements are connected in series through the pulse shaping elements T7 241, T8 243, T9 245 to annular end regions, here represented as the load of C2 247 and R3 249. The switches receive (through R2 203) a voltage U₀ from the charger capacitor C1 201, which is in turn charged up trough R1 205. FIG. 3 shows a scheme with a common charger capacitor for the whole single layer cluster.

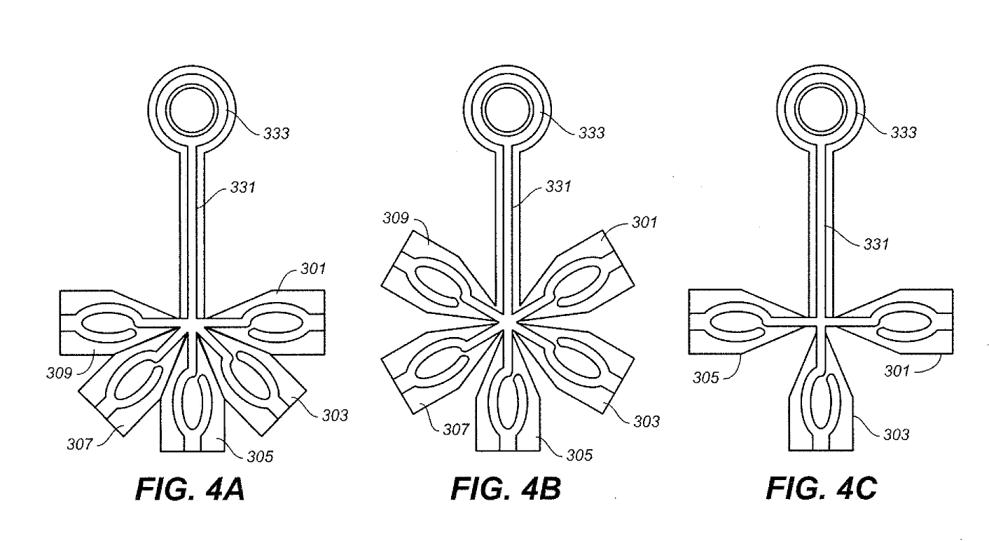

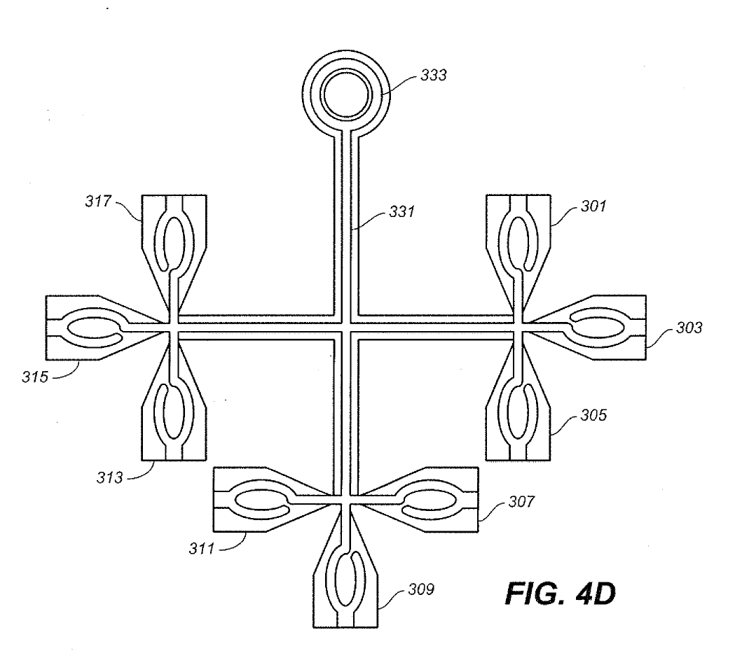

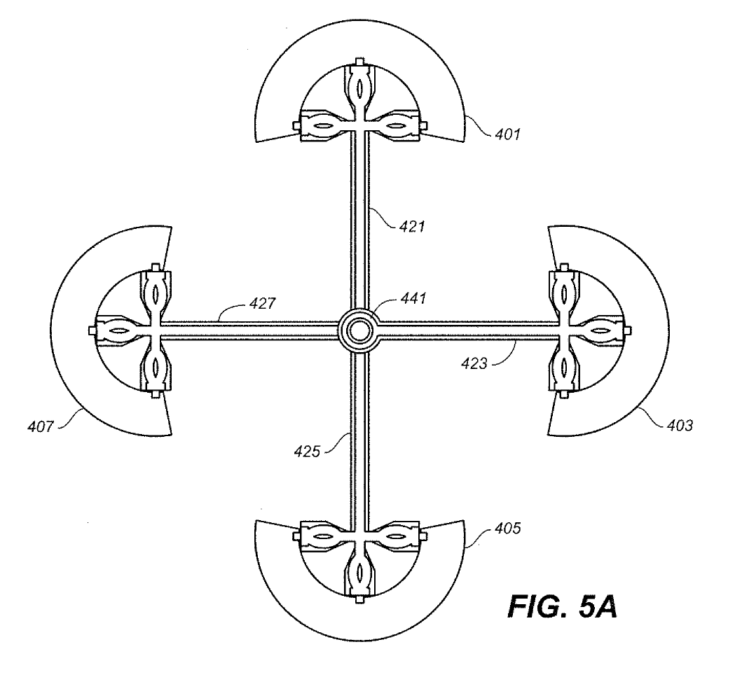

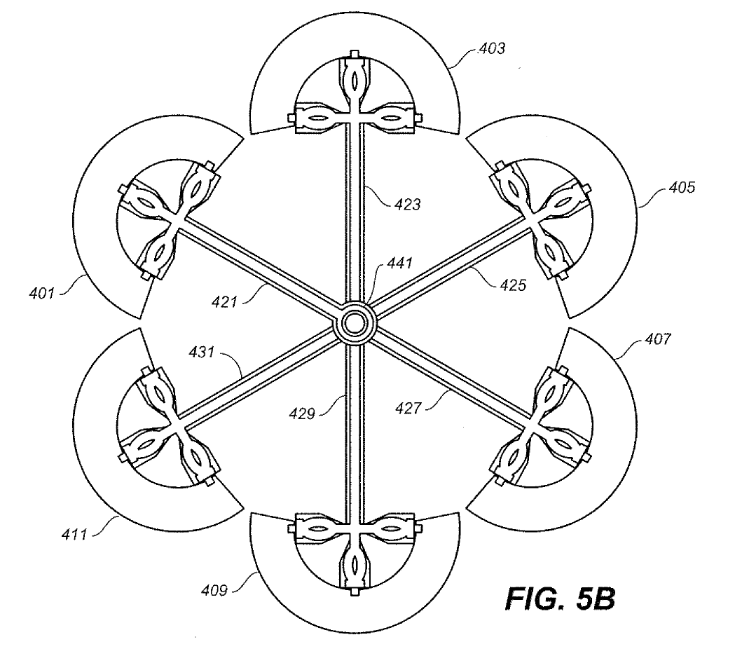

Some examples of different possible cluster designs are shown in FIGS. 4A-D. Various numbers of the individual pulse generation sections (301-317) can be arranged at different axial angles on the one end of the transmission line 331 opposite the ring end 333, or even, as in FIG. 4D, clumped in sub-clusters. The different cluster layer devices can then be stacked by connecting the output ring-like TLs together, each on top of another, with additional rotation of the cluster layer device relative to the previous one by some angle, around the axis of the accelerator beam. FIGS. 5A and 5B show a “top view” for two examples of such layered cluster devices 401-411 with transmission lines 421-431 ending in the rings, where only the top most 441 is shown in this view. (Here, the capacitors are shown, unlike in FIGS. 4A-D.) The angles between TLT devices in the clusters, and the angles between the transmission lines in layered cluster device that are connecting clusters to the output transmission line rings, are not limited by 180°, 90°, 60°, 30°, but can be any other as well.

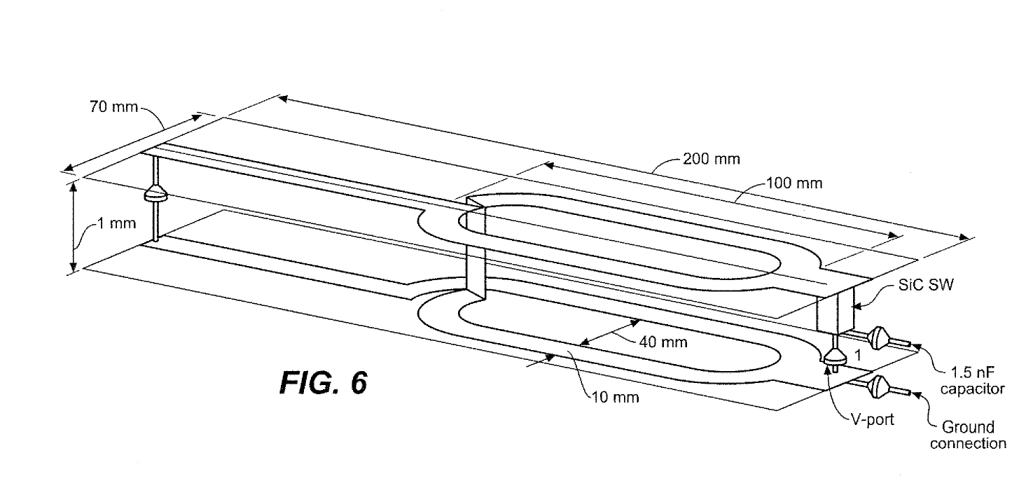

FIGS. 6-9A are schematic views for several examples of the layered cluster device. The dimension in these figure are for one particular set of embodiments, but other values can be used as appropriate for the application. The silicon carbide switch is connected to the signal (top) strip of the pulse generating section, as well as to the capacitor. (In the schematic of FIG. 6, several “V-ports” are shown, which are virtual voltage probes for simulation purposes and would not be part of an actual pulse generating unit.) These individual sections are then formed into a cluster. As noted, each pulse generating section's switch can have its own capacitor, a common capacitor can be shared by all of the sections of a cluster, or there can be some intermediate level of sharing. (As discussed further in U.S. patent application Ser. No. 13/352,187, the charge capacitance is not discharged completely when the switch is in the on-state.)

FIG. 7 is a schematic view of four of the TLT structures of FIG. 6 assembled into a single 4 TLT cluster layer. FIG. 8 then combines two of these 4 TLT clusters with their ring structures aligned along the accelerator's axis. In FIG. 8, there are two rings at center, one from each cluster, although only one of these is clearly visible. In an alternate embodiment this could be a single ring, but having separate rings for each cluster usually provides for greater production simplicity.

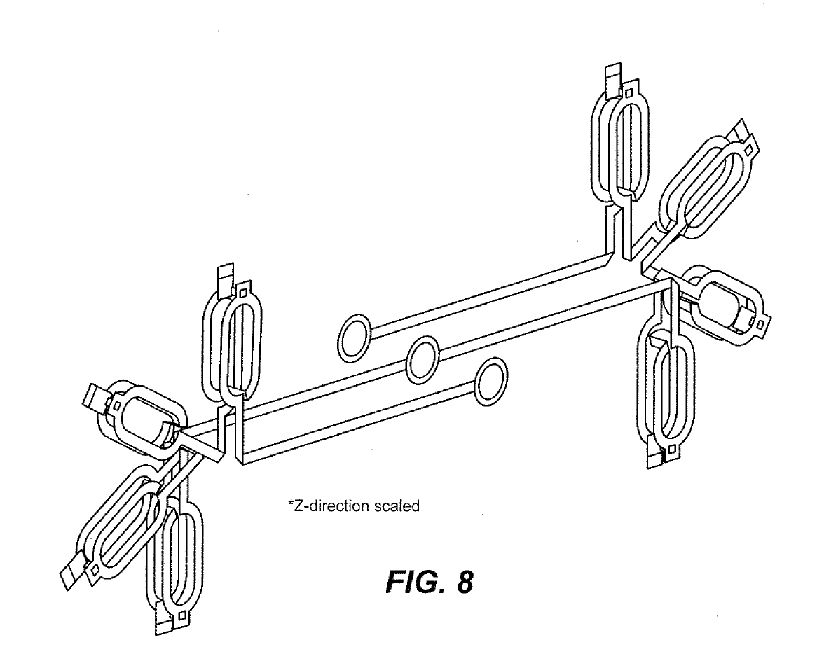

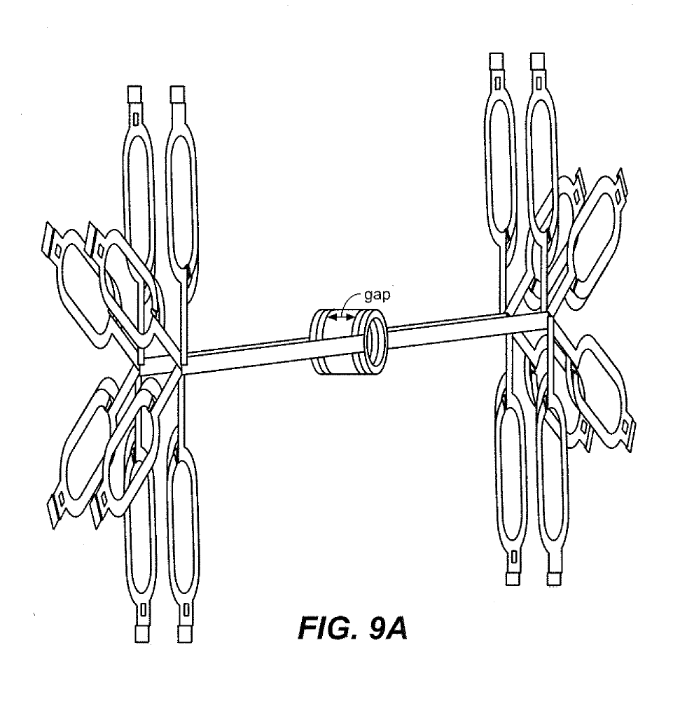

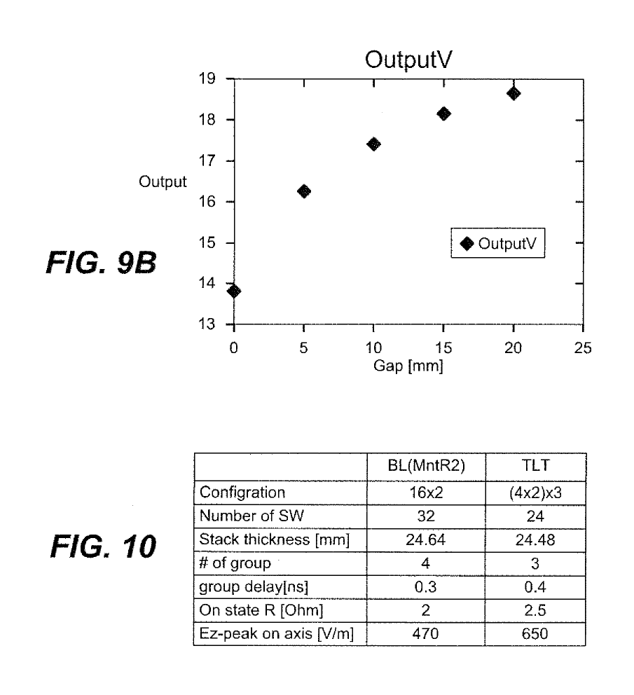

FIG. 9A combines a pair of the structures from FIG. 8 into 4 cluster layers each with 4TLT clusters and having a gap between the first two and second two cluster layers. FIG. 9B shows the CAD simulated output of the layered cluster device vs. gap between layers. It illustrates the importance of the layered cluster structure and having a gap between vertically adjacent layers. As shown, increasing this gap improves the output, although this makes the total device height greater.

Relative to other designs of the same stack thickness, such as stacked blumleins, the arrangement described above can provide higher peak on axis electric field levels with fewer switches. FIG. 10 is a table showing simulated parameters for standard vertical stack of blumleins (see U.S. Pat. No. 7,173,385 of G. Caporaso et al.) vs. a layered cluster design formed of TLTs such as in FIG. 9, but with an additional pair of clusters.

In addition to this gap size, a number of other factors are important to the performance of the high voltage RF multiplier. One of set of factors are the transmission line impedances (transmission lines of the shaper, ladder-like elements, and output shaper) and length (transmission time). Another is the output load impedance, especially the capacitance, as represented by C2 247 and R3 249 in FIG. 3 for one cluster. The charge capacitance (C1 201 in FIG. 3, 101 in FIGS. 1-2) and pulse duration are additional factors.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

1. A method of forming a particle accelerator, comprising:
forming a plurality of clusters, each cluster including a transmission line with first and second strip electrodes respectively ending in first and second annular electrodes, a capacitor section, and a plurality of pulsing forming lines, wherein each pulse forming line includes a pulse generation section and a switch, wherein forming each of the clusters comprises:
connecting the pulse forming lines in series between the first and second strip electrodes;
connecting the switch of each pulse forming line between an electrode of the capacitor section and a signal line conductor of the corresponding pulse generation section;
centering the first and second annular electrodes along the axis of the accelerator;
arranging at least a portion of the transmission line to extend radially away from the axis of the accelerator; and
arranging the pulse forming lines to be splayed out axially from an end of the transmission line section without the annular electrodes, and
arranging the clusters so that their respective transmission lines do not all extend away from the axis of the accelerator with the same axial angle.

2. The method of claim 1, further comprising:
arranging the clusters in pairs opposite each other around the axis of the accelerator.

3. The method of claim 1, wherein the pulse generating sections are transmission line transformers.

4. The method of claim 3, wherein the transmission line section of each cluster comprises an output pulse shaper.

5. The method of claim 1, wherein the pulse generating sections are blumlein structures.

6. The method of claim 1, wherein the pulse generation sections of each cluster are splayed in a coplanar manner.

7. The method of claim 1, wherein the pulse generation sections of each cluster are splayed in a non-coplanar manner.

8. The method of claim 1, wherein the switches are optically activated.

9. The method of claim 1, further comprising:
arranging the pulsing forming lines of each cluster to provide a gap between the individual switches thereof.

10. The method of claim 9, wherein each of the switches are connected to the signal line conductor of the corresponding pulse generation section by way of a switch electrode on a first surface of the respective switch, the method further including:
arranging the switches to provide a free space around the first surface and switch electrode of the individual switches.

11. A particle accelerator, comprising:
a plurality of clusters, each cluster including
first and second transmission line sections respectively ending in first and second annular electrodes centered along the axis of the accelerator;
a capacitor section; and
a plurality of pulsing forming lines connected in series between the first and second transmission line section, wherein each pulse forming line includes:
a pulse generation section; and
a switch connected between an electrode of the capacitor section and a signal line conductor of the pulse generation section,
wherein at least a portion of the transmission line sections extend radially away from the axis of the accelerator with the pulse forming lines splayed out axially from an end of the transmission line section without the annular electrodes, and
wherein the clusters are arranged so that their respective transmission line sections do not all extend away from the axis of the accelerator with the same axial angle.

12. The particle accelerator of claim 11, wherein the clusters are arranged in pairs opposite each other around the axis of the accelerator.

13. The particle accelerator of claim 11, wherein the pulse generating sections are transmission line transformers.

14. The particle accelerator of claim 13, wherein the transmission line section of each cluster comprises an output pulse shaper.

15. The particle accelerator of claim 11, wherein the pulse generating sections are blumlein structures.

16. The particle accelerator of claim 11, wherein the pulse generation sections of each cluster are splayed in a coplanar manner.

17. The particle accelerator of claim 11, wherein the pulse generation sections of each cluster are splayed in a non-coplanar manner.

18. The particle accelerator of claim 11, wherein the switches are optically activated.

19. The particle accelerator of claim 18, further comprising a laser connectable to illuminate the switches.

20. The particle accelerator of claim 11, wherein the pulsing forming lines of each cluster are arranged to provide a gap between the individual switches thereof.

21. The particle accelerator of claim 20, wherein each of the switches are connected to the signal line conductor of the corresponding pulse generation section by way of a switch electrode on a first surface of the respective switch, and wherein the switches are arranged to provide a free space around the first surface and switch electrode of the individual switches.
